(19) United States
(12) Patent Application Publication
(10) Pub. No.: US 2025/0353045 A1
(43) Pub. Date: Nov. 20, 2025

(54) SUBSTRATE PROCESSING APPARATUS

(71) Applicant: SEMES CO., LTD., Cheonan-si (KR)

(72) Inventors: Eun Seok KIM, Asan-si (KR); Yong Hyun CHOI, Cheonan-si (KR); Seung Hoon OH, Cheonan-si (KR)

(73) Assignee: SEMES CO., LTD., Cheonan-si (KR)

(21) Appl. No.: 19/207,992

(22) Filed: May 14, 2025

(30) Foreign Application Priority Data
May 14, 2024 (KR) 10-2024-0062852

(51) Int. Cl. B08B 7/00

(52) U.S. Cl. CPC B08B 7/0021

(57) ABSTRACT

The present disclosure provides a substrate processing apparatus. The substrate processing apparatus includes: a housing having a first body and a second body providing a processing space therein for processing substrates by being combined with each other; an actuator sealing or opening the processing space by moving the second body in a vertical direction with respect to the first body; a supply pipe supplying fluid to the processing space; and a discharge pipe discharging fluid from the processing space, the supply pipe includes: a first upstream pipe connected to a fluid supply source; a first downstream pipe connected to the second body; and a first coil pipe connected to the first upstream pipe and the first downstream pipe and being extendable and contractible in the vertical direction, and the discharge pipe includes: a second upstream pipe connected to the second body; a second downstream pipe disposed downstream of the second upstream pipe; and a second coil pipe connected to the second upstream pipe and the second downstream pipe and being extendable and contractible in the vertical direction, and any one coil pipe of the first coil pipe and the second coil pipe is disposed to surround the other coil pipe when viewed from above.

### CROSS-REFERENCE TO RELATED APPLICATIONS

This application claims priority to and the benefit of Korean Patent Application No. 10-2024-0062852 filed in the Korean Intellectual Property Office on May 14, 2024, the entire contents of which are incorporated herein by reference.

### TECHNICAL FIELD

The present disclosure relates to a substrate processing apparatus and, in more detail, a substrate processing apparatus that perform a drying process on substrates.

### BACKGROUND ART

In general, in order to manufacture semiconductor devices, various processes such as a photo process, an etching process, an ion implantation process, and a deposition process are performed. Further, various foreign substances such as particles, organic contaminants, and metal impurities are generated during these processes. Such foreign substances act as factors that cause defects in substrates and directly affect the performance and yield of semiconductor devices. Accordingly, a semiconductor manufacturing process is necessarily accompanied by a cleaning process for removing such foreign substances.

A general cleaning process includes a chemical processing process for removing foreign substances on a substrate using chemicals, a rinsing process for replacing the chemicals remaining on the substrate with a rinse solution, a solvent processing process for processing the rinse solution on the substrate with an organic solvent, and a drying process for removing the solvent on the substrate.

Recently, a supercritical drying process, which dries a substrate by supplying a fluid in a supercritical state into a high-pressure chamber, is used as a drying process.

FIG. 1 shows an example of a typical apparatus for performing supercritical drying on a substrate.

Referring to FIG. 1, a substrate processing apparatus 5000 includes a first body 5100 and a second body 5200, which provide a processing space inside, and the second body 5200 moves in the vertical direction with respect to the first body 5100.

A supply pipe 5300 for supplying supercritical fluid and a discharge pipe 5400 for discharging supercritical fluid are connected to the second body 5200.

In this structure, due to repeated movement of the second body 5200 in the vertical direction, the supply pipe 5300 and the discharge pipe 5400 coupled to the second body 5200 may be deformed or damaged. In order to solve this problem, part of the pipes is provided as coil pipes 5350 and 5450 to allow flexibility with the movement of the second body.

However, coil pipes occupy more area compared to regular pipes, so it is difficult to install them in a limited space when a plurality of pipes is connected to the second body.

### SUMMARY OF THE INVENTION

An objective of the present disclosure is to provide a substrate processing apparatus that can reduce the area occupied by multiple coil pipes in substrate processing apparatuses including a plurality of coil pipes connected to a body that is vertically driven.

Another objective of the present disclosure is to provide a substrate processing apparatus that can prevent abrupt changes in temperature or pressure of a processing fluid when supplying the processing fluid to a processing space through a supply pipe connected to a body, which is vertically driven, and including a coil pipe.

Effects of the present disclosure are not limited to those described above and effects not stated above will be clearly understood to those skilled in the art from the specification and the accompanying drawings.

An exemplary embodiment of the present disclosure, a substrate processing apparatus, comprising: a housing having a first body and a second body providing a processing space therein for processing substrates by being combined with each other; an actuator sealing or opening the processing space by moving up and down the second body with respect to the first body; a supply pipe supplying fluid to the processing space; and a discharge pipe discharging fluid from the processing space, wherein the supply pipe includes: a first upstream pipe connected to a fluid supply source; a first downstream pipe connected to the second body; and a first coil pipe connected to the first upstream pipe and the first downstream pipe and having a coil shape extendable and contractible in a vertical direction, and wherein the discharge pipe includes: a second upstream pipe connected to the second body; a second downstream pipe disposed downstream of the second upstream pipe; and a second coil pipe connected to the second upstream pipe and the second downstream pipe and having a coil shape extendable and contractible in a vertical direction, and any one coil pipe of the first coil pipe and the second coil pipe may be disposed to surround the other coil pipe when viewed from above.

According to an embodiment of the present disclosure, the first coil pipe may be disposed to surround the second coil pipe when viewed from above.

According to an embodiment of the present disclosure, a cross-sectional area of the second coil pipe may be provided to be smaller than a cross-sectional area of the first coil pipe.

According to an embodiment of the present disclosure, the cross-sectional area of the first coil pipe may be provided to be the same as a cross-sectional area of the first upstream pipe and a cross-sectional area of the first downstream pipe.

According to an embodiment of the present disclosure, the cross-sectional area of the second coil pipe may be provided to be smaller than a cross-sectional area of the second upstream pipe and a cross-sectional area of the second downstream pipe.

According to an embodiment of the present disclosure, a cross-sectional area of the first coil pipe may be provided to be the same as a cross-sectional area of the second coil pipe.

According to an embodiment of the present disclosure, a central axis of the first coil pipe may be disposed to be spaced apart from a central axis of the second coil pipe when viewed from above.

According to an embodiment of the present disclosure, a central axis of the first coil pipe and a central axis of the second coil pipe may be provided to coincide with each other when viewed from above.

According to an embodiment of the present disclosure, the apparatus may further include an upper supply pipe coupled to the first body and supplying fluid to the processing space, wherein one of the supply pipe and the discharge pipe is directly connected to a center of the second body, and the other one of the supply pipe and the discharge pipe may be directly connected to a point offset from the center of the second body.

According to an embodiment of the present disclosure, an axial length of the first coil pipe and an axial length of the second coil pipe may be provided to be the same.

An exemplary embodiment of the present disclosure, a substrate processing apparatus, comprising: a housing having a first body and a second body providing a processing space therein for processing substrates by being combined with each other; an actuator sealing or opening the processing space by moving the second body with respect to the first body; a supply pipe supplying fluid to the processing space; and a discharge pipe discharging fluid from the processing space, wherein any one pipe of the supply pipe and the discharge pipe has a first coil pipe having a coil shape extendable and contractible along a relative movement direction, and the other one pipe of the supply pipe and the discharge pipe may has an inner pipe that passes through a region surrounded by the first coil pipe.

According to an embodiment of the present disclosure, the inner pipe may be a second coil pipe having a coil shape extendable and contractible along the relative movement direction.

According to an embodiment of the present disclosure, a longitudinal direction of the inner pipe may be provided to be the same as an axial direction of the first coil pipe.

According to an embodiment of the present disclosure, the supply pipe includes: a first upstream pipe connected to a fluid supply source; a first downstream pipe connected to the second body; and the first coil pipe connected to the first upstream pipe and the first downstream pipe, and the discharge pipe includes: a second upstream pipe connected to the second body; a second downstream pipe disposed downstream of the second upstream pipe; and the inner pipe connected to the second upstream pipe and the second downstream pipe.

According to an embodiment of the present disclosure, the relative movement direction may be a vertical direction.

According to an embodiment of the present disclosure, a cross-sectional area of the second coil pipe may be provided to be smaller than a cross-sectional area of the first coil pipe.

According to an embodiment of the present disclosure, a cross-sectional area of the first coil pipe may be provided to be the same as a cross-sectional area of the first upstream pipe and a cross-sectional area of the first downstream pipe.

An exemplary embodiment of the present disclosure, a substrate processing apparatus, comprising: a housing having a first body and a second body providing a processing space therein for processing substrates by being combined with each other; a supporting unit coupled to the first body and supporting a substrate in the processing space; an actuator sealing or opening the processing space by moving up and down the second body with respect to the first body; a supply pipe supplying fluid to the processing space; and a discharge pipe discharging fluid from the processing space, the supply pipe includes: a first upstream pipe connected to a fluid supply source; a first downstream pipe connected to the second body; and the first coil pipe connected to the first upstream pipe and the first downstream pipe, and having a coil shape, the discharge pipe includes: a second upstream pipe connected to the second body; a second downstream pipe disposed downstream of the second upstream pipe; and the second coil pipe connected to the second upstream pipe and the second downstream pipe, and having a coil shape, the first coil pipe is disposed to surround the second coil pipe when viewed from above, and a cross-sectional area of the second coil pipe may be provided to be smaller than a cross-sectional area of the first coil pipe.

According to an embodiment of the present disclosure, the cross-sectional area of the first coil pipe is provided to be the same as the cross-sectional area of the first upstream pipe and a cross-sectional area of the first downstream pipe; and the cross-sectional area of the second coil pipe may be provided to be smaller than a cross-sectional area of the second upstream pipe and a cross-sectional area of the second downstream pipe.

According to an embodiment of the present disclosure, the apparatus may further include an upper supply pipe coupled to the first body and supplying fluid to the processing space, wherein one of the supply pipe and the discharge pipe is directly connected to a center of the second body, and the other one of the supply pipe and the discharge pipe may be directly connected to a point offset from the center of the second body.

According to an embodiment of the present disclosure, n a substrate processing apparatus including a plurality of coil pipes connected to a body that is moved up and down, an occupied area by the plurality of coil pipes can be reduced.

According to an embodiment of the present disclosure, when a processing fluid is supplied into a processing space through a supply pipe connected to a body, which is moved up and down, and including a coil pipe, a sudden change in temperature or pressure of the processing fluid can be prevented.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a plan view schematically showing an example of a typical apparatus for performing supercritical drying on substrates.

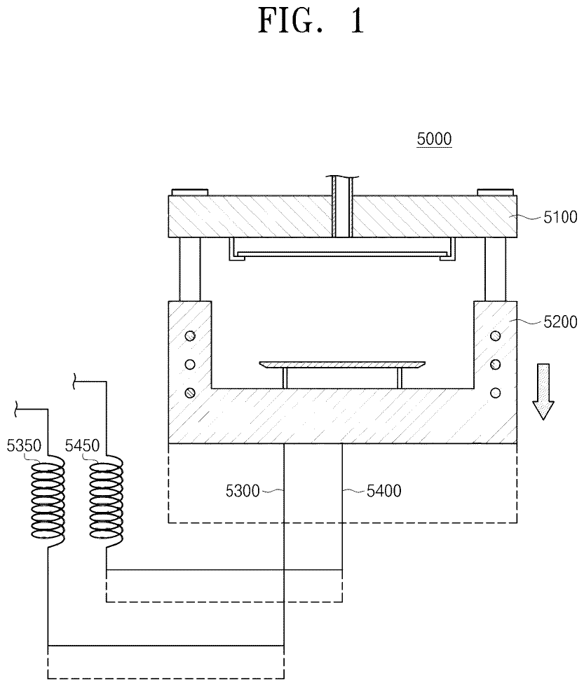

FIG. 2 is a plan view schematically showing a substrate processing apparatus according to an embodiment of the present disclosure.

FIG. 3 is a view schematically showing an embodiment of a liquid processing chamber of the substrate processing apparatus of FIG. 2.

FIG. 4 is a view schematically showing an embodiment of a drying chamber of the substrate processing apparatus of FIG. 2.

FIG. 5 is a view schematically showing the structure of a first coil pipe and a second coil pipe according to an embodiment of the present disclosure.

FIG. 6 is a view schematically showing a part of the appearance when the first coil pipe and the second coil pipe according to an embodiment of the present disclosure are cut along a plane including the central axis.

FIG. 7 is a flowchart illustrating a method of performing a supercritical drying process.

FIG. 8 is a view schematically showing the drying chamber when a second body of a housing is raised with respect to a first body in a substrate loading step.

FIG. 9 is a view schematically showing the drying chamber when a second body of a housing is lowered with respect to a first body in a substrate loading step.

FIG. 10 is a view schematically showing another embodiment of the first coil and the second coil of FIG. 5.

FIG. 11 (a) is a view schematically showing another embodiment of the first coil and the second coil of FIG. 5.

FIG. 11 (b) is a view schematically showing a portion of the appearance when the first coil pipe and the second coil pipe of FIG. 11 (a) are cut along a plane including the central axis.

FIGS. 12 to 14 are views each schematically showing another embodiment of the drying chamber of FIG. 14.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

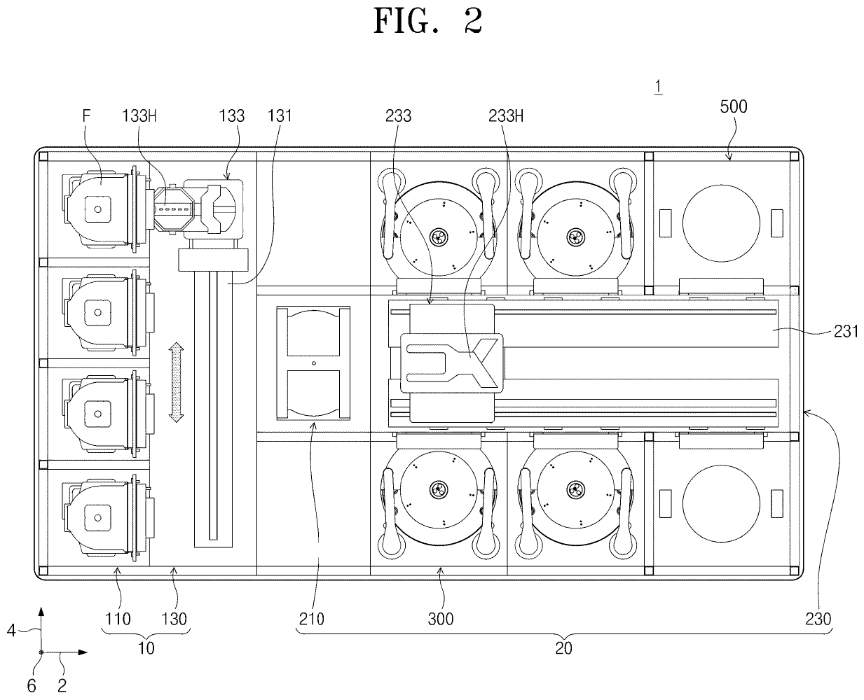

Hereafter, embodiments of the present disclosure are described with reference to FIG. 2 to FIG. 14.

FIG. 2 is a plan view schematically showing a substrate processing apparatus according to an embodiment of the present disclosure. A substrate processing apparatus 1 includes an index module 10 and a processing module 20. According to an embodiment, the index module 10 and the processing module 20 are disposed in one direction. Hereafter, the direction in which the index module 10 and the processing module 20 are arranged is referred to as a first direction 2, a direction perpendicular to the first direction 2 when seen from above is referred to as a second direction 4, and a direction perpendicular to both of the first direction 2 and the second direction 4 is referred to as a third direction 6.

The index module 10 transfers substrates W from containers F having the substrates W therein to the processing module 20 that processes the substrates W. The index module 10 stores substrates W, which have been processed by the treating module 20, into the containers F. The longitudinal direction of the index module 10 is provided in the second direction 4. The index module 10 has a load port 110 and an index frame 130.

A container F having a substrate W therein is seated in the load port 110. The load port 110 is positioned at the opposite side to the processing module 20 with the index frame 130 therebetween. A plurality of load ports 110 may be provided. The plurality of load ports 110 may be disposed in one line in the second direction 4. The number of the load ports 110 may be increased or decreased, depending on the process efficiency, a footprint condition, etc. of the processing module 20.

Multiple slots (not shown) for accommodating substrates W disposed in parallel with the ground are formed on the container F. The container F may be a container for sealing such as a Front Opening Unified Pod (FOUP). The container F may be placed onto the load port 110 by a worker or a conveying device (not shown) such as an overhead transfer, an overhead conveyor, or an automatic guided vehicle.

An index rail 131 and an index robot 133 are provided inside the index frame 130. The index rail 131 is provided inside the index frame 130 with its longitudinal direction aligned along the second direction 4. The index robot 133 can transfer substrates W. The index robot 133 can transfer substrates W between the index module 10 and a buffer unit 210 to be described below.

The index robot 133 may be provided on the index rail 131 to be movable in the second direction 4. The index robot 133 includes a hand 133H. Substrates W can be placed on the hand 133H. The hand 133H is provided to be movable forward and backward in the first direction 2. Further, the hand 133H may be provided to be able to rotate around the third direction 6 and move in the third direction 6. A plurality of hands 133H may be provided. The plurality of hands 133H may be provided to be spaced in the vertical direction. The plurality of hands 133H can move forward and backward and rotate independently from each other.

The processing module 20 includes a buffer unit 210, a transfer chamber 230, a liquid processing chamber 300, and a drying chamber 500. The buffer unit 210 provides a space in which substrates W that are loaded into the processing module 20 and substrates W that are unloaded from the processing module 20 temporarily stay. The transfer chamber 230 provides spaces for transferring substrates W between the buffer unit 210 and the liquid processing chamber 300, between the liquid processing chamber 300 and the drying chamber 500, and between the drying chamber 500 and the buffer unit 210. The liquid processing chamber 300 performs a liquid processing process of performing liquid processing on substrates W by supplying a liquid onto the substrates W. For example, the liquid processing process may be a cleaning process of cleaning substrates W with a cleaning solution. The driving chamber 500 performs a process of drying liquid remaining substrates W that have undergone liquid processing.

The buffer unit 210 may be disposed between the index frame 130 and the transfer chamber 230. The buffer unit 210 may be positioned at an end of the transfer chamber 230. Slots (not shown) in which substrates W are placed are provided in the buffer unit 210. A plurality of slots (not shown) may be provided to be spaced apart from each other in the third direction 6. The buffer unit 210 is open on the front face and the rear face. The front face may be a surface that faces the index module 20 and the rear face may be a surface that faces the transfer chamber 230. The index robot 133 can approach the buffer unit 210 through the front face and the transfer robot 233 can approach the buffer unit 210 through the rear face.

The longitudinal direction of the transfer chamber 230 may be provided in the first direction 2. The liquid processing chamber 300 and the drying chamber 500 may be disposed along the first direction at a side of the transfer chamber 230. The liquid processing chamber 300 disposed at the side may be disposed closer to the index module 10 than the drying chamber 500 disposed at the same side, in the first direction 2. The transfer chamber 230 and the liquid processing chamber 300, or the transfer chamber 230 and the drying chamber 500 may be disposed along the second direction 4.

According to an embodiment, the liquid processing chamber 300 and the drying chamber 500 are disposed at both sides of the transfer chamber 230, respectively, and the liquid processing chambers 300 and the drying chambers 500 may be provided in arrays of A×C1 and B×C2 (where A, B, C1, and C2 are natural numbers equal to or greater than 1), respectively, along the first direction 2 and the third direction 6 at a side of the transfer chamber 230. In this case, A is the number of liquid processing chambers 300 provided in a line along the first direction 2, C1 is the number of liquid processing chambers 300 provided in a line along the third direction 6, B is the number of drying chambers 500 provided in a line along the first direction 2, and C2 is the number of drying chambers 500 provided in a line along the third direction 6. For example, when four or six liquid processing chambers 300 and drying chambers 500 are provided at a side of the transfer chamber 230, respectively, the liquid processing chambers 300 and the drying chambers 500 may be disposed in arrays of 2×2 or 2×3, respectively. The numbers of liquid processing chambers 300 and drying chambers 500 may be increased or decreased. Unlike the above descriptions, the liquid processing chambers 300 and drying chambers 500 may be provided only at a side of the transfer chamber 230, and may be provided in a single layer at a side or both sides of the transfer chamber 230. Further, only the liquid processing chambers 300 may be provided at a side of the transfer chamber 230, and only the drying chambers 500 may be provided at the other side.

The transfer frame 230 has a guide rail 231 and a transfer robot 233. The guide rail 231 is provided in the transfer frame 230 with its longitudinal direction aligned along the first direction 2. The transfer robot 233 may be provided on the guide rail 231 to be movable in a straight line in the first direction 2. The transfer robot 233 provides spaces for transferring substrates W between the buffer unit 210 and the liquid processing chamber 300, between the liquid processing chamber 300 and the drying chamber 500, and between the drying chamber 500 and the buffer unit 210.

The transfer robot 233 includes a hand 233H on which a substrate W is placed. The hand 233H may be provided on the guide rail 231 to be movable in the first direction 2. Accordingly, the hand 233H can move forward and backward along the guide rail 231. Further, the hand 133H may be provided to be able to rotate around the third direction 6 and move in the third direction 6. A plurality of hands 233H may be provided. The plurality of hands 233H may be provided to be spaced in the vertical direction. The plurality of hands 233H can move forward and backward and rotate independently from each other.

The liquid processing chamber 300 performs a process for liquid processing on substrates M. For example, the liquid processing chamber 300 may be a chamber that performs a cleaning process of removing process byproducts attached to substrates W.

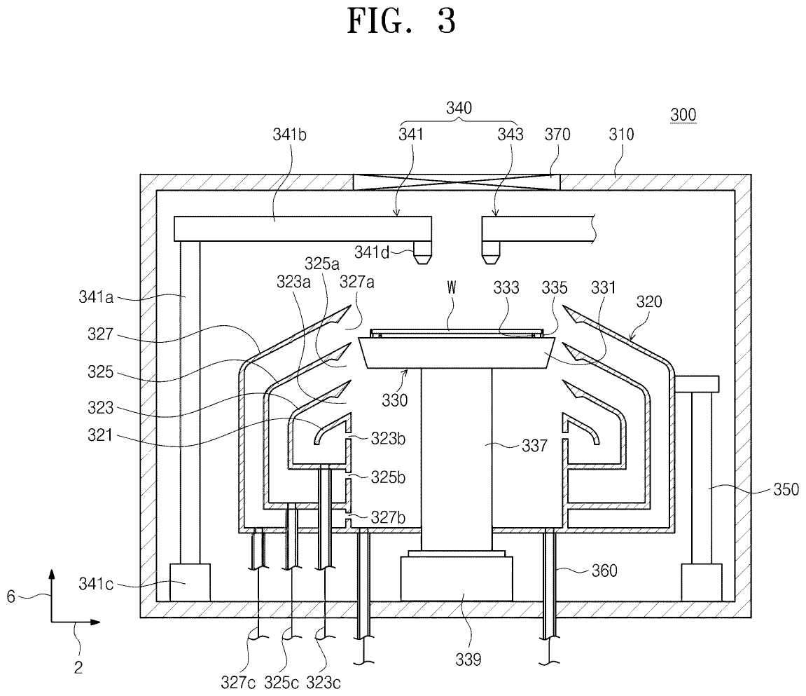

FIG. 3 is a view schematically showing an embodiment of a liquid processing chamber of the substrate processing apparatus of FIG. 2. A process chamber includes a housing 310, a processing container 320, a supporting unit 330, a liquid supply unit 340, a lifting unit 350, an exhaust unit 360, and an airflow supply unit 370.

The housing 310 has an internal space. The housing 310 is provided in a substantially rectangular parallelepiped shape. An opening (not shown) is formed on a side of the housing 310. The opening (not shown) serves as a port through which substrates W are loaded into the internal space or substrates W are unloaded from the internal space. The processing container 320, the supporting unit 330, the liquid supply unit 340, and the airflow supply unit 370 are disposed in the housing 310.

The processing container 320 has a processing space with an open top. The processing container 320 may have a bowl shape. A substrate W is positioned in the processing space and a liquid is supplied onto the substrate W in the processing space. A plurality of types of liquids is provided and may be sequentially supplied to a substrate W.

The processing container 320 may have a plurality of recovery tanks 323, 325, and 327. The recovery tanks 323, 325, and 327 recover different liquids from liquids used to process substrates W. The tanks 323, 325, and 327 each have a recovery space for recovering liquids used to process substrates W, respectively. A guide wall 321 is provided in a ring shape surrounding the tanks 323, 325, and 327 and the supporting unit 330. When a liquid processing process is performed, liquids scattered by rotation of substrates W are introduced into the recovery spaces through inlets 323a, 325a, and 327a of the respective recovery tanks to be described below.

According to an embodiment, the processing container 320 has a guide wall 321, a first recovery tank 321, a second recovery tank 325, and a third recovery tank 327. The guide wall 321 is provided in a ring shape surrounding the supporting unit 330 and the first recovery tank 323 is provided in a ring shape surrounding the guide wall 321. The second recovery tank 325 is provided in the shape of a ring shape surrounding the first recovery tank 323, and the third recovery tank 327 is provided in a ring shape surrounding the second recovery tank 325. The space between the first recovery tank 323 and the guide wall 321 functions as a first inlet 323a through which liquid flows inside. The space between the first recovery tank 323 and the second recovery tank 325 functions as a second inlet 325a through which liquid flows inside. The space between the second recovery tank 325 and the third recovery tank 327 functions as a third inlet 327a through which liquid flows inside. The second inlet 325a may be positioned higher than the first inlet 323a, and the third inlet 327a may be positioned higher than the second inlet 325a

The space between the lower end of the guide wall 321 and the first recovery tank 323 functions as a first outlet 323b for discharging fumes and airflow generated from liquids. The space between the lower end of the first recovery tank 323 and the second recovery tank 325 functions as a second outlet 325b for discharging fumes and airflow generated from liquids. The space between the lower end of the second recovery tank 325 and the third recovery tank 327 functions as a third outlet 327b for discharging fumes and airflow generated from liquids. Fumes and airflow discharged from the first outlet 323b, the second outlet 325b, and the third outlet 327b are exhausted through the exhaust unit 360 to be described below.

Recovery lines 323c, 325c, and 327c, which extend vertically downward from the bottom surfaces, are connected to the recovery tanks 323, 325, and 327, respectively. The recovery lines 323c, 325c, and 327c discharge the processing liquids introduced through the recovery tanks 323, 325, and 327, respectively. The discharged processing liquids can be reused through an external processing liquid regeneration system (not shown).

The supporting unit 330 supports substrates W in the processing space. The supporting unit 330 has a spin chuck 331, a supporting pin 333, a chuck pin 335, a rotary shaft 337, and an actuator 339.

The upper surface of the spin chuck 331 is provided in a substantially circular shape when viewed from above. The upper surface of the spin check 331 may have a diameter larger than those of substrates W.

A plurality of supporting pins 333 is provided. The supporting pins 333 are disposed on the upper surface of the spin chuck 331. The supporting pins 333 are disposed at predetermined intervals along the edge of the upper surface of the spin chuck 331. The supporting pins 333 protrude upward from the upper surface of the spin chuck 331. The supporting pins 333 are disposed to form an overall ring shape through their combination. The supporting pins 333 support the edge of the back of a substrate W such that the substrate W is spaced a predetermined distance apart from the upper surface of the spin chuck 331.

A plurality of chuck pins 335 is provided. The chuck pins 335 are disposed farther from the center of the spin chuck 331 than the supporting pins 333. The chuck pins 335 protrude from the upper surface of the spin chuck 331. When a substrate W is rotated, the chuck pins 335 support the side of the substrate W to prevent lateral shifting from its fixed position. The chuck pins 335 are provided to be movable between a standby position and a supporting position in the radial direction of the spin chuck 331. As an example, the chuck pins 335 can be moved in a line in the radial direction of a substrate W between the standby position and the supporting position. The standby position is a position farther from the center of the spin chuck 331 than the supporting position. When a substrate W is loaded or unloaded onto or from the supporting unit 330, the chuck pins 335 are positioned at the standby position, and when a process is performed on a substrate W, the chuck pins 335 are positioned at the supporting position. The chuck pins 335 are in contact with the side of a substrate at the supporting position.

The rotary shaft 337 is coupled to the spin chuck 331. The rotary shaft 337 is coupled to the bottom surface of the spin chuck 331. The rotary shaft 337 may be provided with its longitudinal direction aligned in the vertical direction. The rotary shaft 337 is provided to be rotatable by power from the actuator 339. As the rotary shaft 337 is rotated by the actuator 339, the rotary shaft 337 rotates the spin chuck 331. The actuator 339 can change the rotation speed of the rotary shaft 337. The actuator 339 may be a motor that provides a driving force. However, the actuator is not limited thereto and may be modified as well-known devices that provide a driving force.

The liquid supply unit 340 supplies liquid to substrates W. The liquid supply unit 340 supplies liquid to a substrate W supported on the supporting unit 330. A plurality of liquid supply units 340 may be provided and they supply different types of liquids, respectively. According to an embodiment, the liquid supply unit 340 may include a first liquid supply member 341 and a second liquid supply member 343.

The first liquid supply member 341 includes a supporting shaft 341a, a supporting arm 341b, an actuator 341c, and a nozzle 341d. The supporting shaft 341a is positioned at a side of the processing container 320. The supporting shaft 341a has a rod shape of which the longitudinal direction aligned in the third direction 3. The supporting shaft 341a is provided to be rotatable by the actuator 341c. The supporting arm 341b is coupled to the upper end of the supporting shaft 341a. The supporting arm 341b vertically extends from the supporting shaft 341a. The nozzle 341 is fixedly coupled to the end of the supporting arm 341b. As the supporting shaft 341a is rotated, the nozzle 341d can be swingably moved with the supporting arm 341b. The nozzle 341 can move to a process position and a standby position by swinging to move. The process position is the position where the nozzle 341d is opposite to a substrate W supported on the supporting unit 330 when viewed from above, and the standby position is the position where the nozzle 341d is away from the process position.

The second liquid supply member 343 can supply a second liquid onto a substrate W supported on the supporting unit 330. The second liquid supply member 343 is provided in the same shape as the first liquid supply member 341. Accordingly, description of the second liquid supply member 343 is omitted.

The first liquid supply member 341 and the second liquid supply member 343 have been described as independent members, but, unlike this, the first liquid supply member 341 and the second liquid supply member 343 may share a single actuator, supporting shaft, and supporting arm, and a first liquid supply nozzle and a second liquid supply nozzle may be coupled to the same supporting arm.

The first liquid and the second liquid may be any one of a chemical, a rinsing solution, and an organic solvent. For example, the chemical may include Diluted Sulfuric acid Peroxide (H₂SO₄), phosphoric acid (P₂O₅), hydrofluoric acid (HF), and ammonium hydroxide (NH₄OH). For example, the rinsing solution may include water or deionized water (DIW). For example, the organic solvent may include alcohol such as Isopropyl Alcohol (IPA).

The lifting unit 350 is disposed in the housing 310. The lifting unit 350 adjusts the relative height between the processing container 320 and the supporting unit 330. The lifting unit 350 can straightly move the processing container 320 in the third direction 6. Unlike the above description, the processing container 320 may be fixed and the lifting unit 350 may move the supporting unit 440 in the vertical direction.

The exhaust unit 360 exhausts fumes and gases generated in the processing space. The exhaust unit 360 exhausts fumes and gases generated when substrates W are subjected to liquid processing. The exhaust unit 360 may be coupled to the bottom of the processing container 320. For example, the exhaust unit 360 may be provided in a space between the rotary shaft 337 of the support unit 330 and an inner wall of the processing container 320. A pressure relief unit (not shown) is provided in the exhaust unit 360. By the pressure relief unit, fumes and gases generated during liquid processing of substrates W are exhausted from the processing space to the outside of the processing space.

The airflow supply unit 370 supplies airflow to the internal space of the housing 310. The airflow supply unit 370 can supply downward airflow to the internal space. The airflow supply unit 370 may be installed on the housing 310. The airflow supply unit 370 may be installed on the ceiling of the housing 310. The gas supplied to the internal space of the housing 310 through the airflow supply unit 370 forms downward airflow in the internal space. Gas byproducts generated by the processing process in the processing space are discharged to the outside of the housing 310 through the exhaust unit 360 by the downward airflow. The airflow supply unit 370 may be provided as a Fan Filter Unit (FFU).

The driving chamber 500 performs a process of drying liquid remaining on substrates W that have undergone liquid processing. The drying chamber 500 can dry the cleaning solution remaining on substrates W by supplying supercritical fluid. For example, the drying chamber 500 can perform a drying process of removing an organic solvent remaining on substrates W using carbon dioxide in a supercritical state.

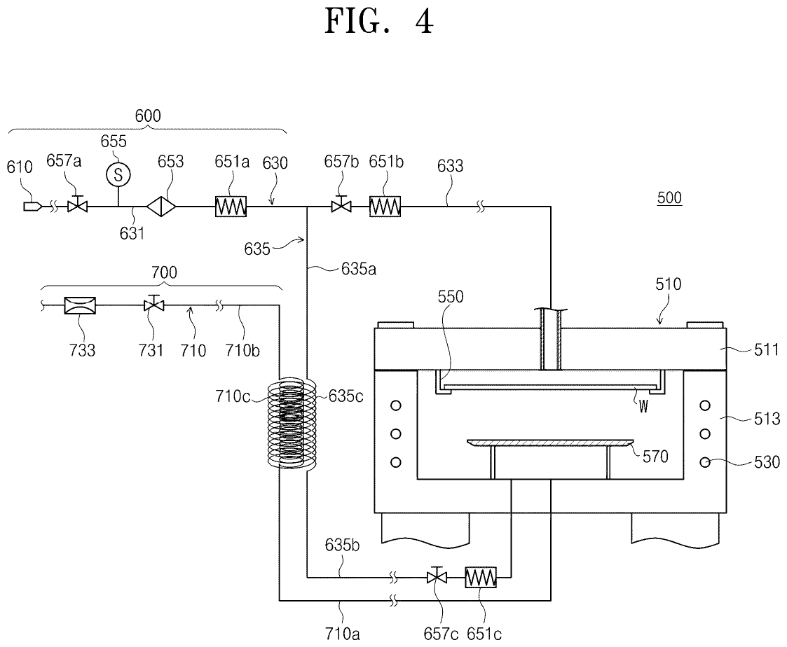

FIG. 4 is a view schematically showing an embodiment of a drying chamber of the substrate processing apparatus of FIG. 2.

The drying chamber 500 according to an embodiment of the present disclosure removes a processing liquid remaining on substrates W using a drying fluid in a supercritical state. For example, the drying chamber 500 can perform a drying process of removing an organic solvent remaining on substrates W using carbon dioxide in a supercritical state.

The drying chamber 500 may include a housing 510, a heating member 530, a supporting unit 550, a blocking plate 570, an actuator 590, a fluid supply unit 600, and a fluid discharge unit 700.

The housing 510 may have a processing space in which substrates W are processed. The housing 510 is made of a material capable of withstanding a high pressure above the critical pressure of supercritical fluid. The housing 510 has a first body 511 and a second body 513. The first body 511 and the second body 513 provide a processing space therein by being combined with each other. The first body 511 may be positioned higher than the second body 513. Any one of the first body 511 and the second body 513 is coupled to the actuator 590 and can be vertically moved. For example, the second body is coupled to the actuator 590 and can be vertically moved by the actuator 590. Accordingly, the processing space of the housing 510 can be opened or sealed, depending on movement of the second body 513.

The heating member 530 heats processing fluid that is supplied to the processing space. The heating member 530 can increase the internal temperature of the processing space. Since the heating member 530 increases the temperature of the processing space, the supplied processing fluid is converted to a supercritical state or is maintained in a supercritical state.

Further, the heating member 530 may be embedded in the housing 510. The heating member 530 may be embedded in at least one of the first body 511 or the second body 513. For example, the heating member 530 may be embedded in each of the first body 511 or the second body 513. The heating member 530 may be a heater 651.

The supporting unit 550 supports a substrate W in the processing space. The supporting unit 550 is coupled to the first body 511 or the second body 513 and can support a substrate W in the processing space. For example, the supporting unit 550 is coupled to the first body 511 and can support a substrate W in the processing space. When the supporting unit 550 is coupled to the first body 511 fixed in position instead of the second body 513 that moves in the vertical direction, it is possible to reduce shaking of a substrate W on the supporting unit 550 when the processing space is opened and closed.

The blocking plate 570 is disposed in the processing space. The blocking plate 570 can prevent substrates W from being damage by processing liquid that is directly discharged toward the substrates W.

The blocking plate 570 may be disposed to be spaced upwardly apart from the underside of the housing 510. For example, the blocking plate 570 can be supported by a support to be spaced upward from the underside of the housing 510. The support may be provided in a rod shape. A plurality of supports may be provided. The supports are provided to be spaced a predetermined distance apart from each other.

The fluid supply unit 600 supplies processing fluid to the processing space. The processing fluid may be carbon dioxide. The processing fluid may be supplied to the processing space in a supercritical state or may be converted to a supercritical state in the processing space.

The fluid supply unit 600 includes a fluid supply source 610, a supply pipe 630, and parts installed in the supply pipe 630. The parts may be a heater 651, a filter 653, a sensor 655, a valve 657, etc.

The fluid supply source 610 stores and supplies processing fluid. The fluid supply source 610 may be a reservoir. The fluid stored in the fluid supply source 610 flows to the processing space through the supply pipe 630.

The supply pipe 630 supplies processing fluid to the processing space. The supply pipe 630 may have a main supply pipe 631, an upper supply pipe 633, and a lower supply pipe 635.

The main supply pipe 631 is connected to the fluid supply source 610. The upper supply pipe 633 and the lower supply pipe 635 diverge from the main supply pipe 631. The main supply pipe 631 receives processing fluid from the fluid supply source 610 and supplies the processing fluid to the upper supply pipe 633 and the lower supply pipe 635. The main supply pipe 631 is provided with a constant cross-sectional area, through which the processing fluid flows, in its longitudinal direction. The heater 651a, the filter 653, the sensor 655, and the valve 657a may be installed in the main supply pipe 631.

Heaters 651a, 651b, 651c heat the pipe, thereby adjusting the temperature of the processing fluid flowing (remaining) in the pipe.

The filter 653 filters the processing fluid that is provided from the fluid supply source 610 to the processing space. For example, the filter 653 can filter out impurities that may be included in the processing fluid that is delivered to the processing space.

The sensor 655 may be a pressure sensor or a temperature sensor. The sensor 654 can measure the temperature or pressure of the processing space and/or the pipe.

Valves 657a, 657b, and 657c may be on/off valves. Selectively, a flow control valve may be further installed in the main supply pipe. Whether the processing fluid is supplied to the processing space is determined, depending on opening and closing of the valves 657a, 657b, and 657c.

The upper supply pipe 633 is connected to the main supply pipe 631 and the first body 511 and supplies processing fluid to the upper area of the processing space. The upper supply pipe 633 may be connected to the center of the first body 511. The heater 651b and the valve 657b may be installed in the upper supply pipe 633. The upper supply pipe 633 is provided with a constant cross-sectional area, through which the processing fluid flows, in its longitudinal direction.

The lower supply pipe 635 is connected to the main supply pipe 631 and the second body 513 and supplies processing fluid to the lower area of the processing space. The lower supply pipe 635 has a first upstream pipe 635a, a first downstream pipe 635b, and a first coil pipe 635c.

The first upstream pipe 635a is connected to the main supply pipe 631. The first upstream pipe 635a is provided with a constant cross-sectional area, through which the processing fluid flows, in its longitudinal direction.

The first downstream pipe 635b is connected to the second body 513. The first downstream pipe 635b may be connected to a point offset from the center of the second body 513. The first downstream pipe 635b is provided with a constant cross-sectional area, through which the processing fluid flows, in its longitudinal direction. For example, the cross-sectional area of the first upstream pipe 635a and the cross-sectional area of the first downstream pipe 635b may be provided to be the same. The heater 651c and the valve 657c may be installed in the first downstream pipe 635b.

The first coil pipe 635c is connected to the first upstream pipe 635a and the first downstream pipe 635b. The first coil pipe 635c is disposed to be extendable and contractible in the vertical direction. The first coil pipe 635c can be extended in the vertical direction by movement of the second body 513 when the second body is driven in the vertical direction. The cross-sectional area of the flow passage of the first coil pipe 635c is provided to be the same as the cross-sectional area of the flow passages of the first upstream pipe 635a and the first downstream pipe 635b. Accordingly, when process fluid passes through the first coil pipe, the temperature of the process fluid is maintained constant.

If the cross-sectional area of the flow passage through which process fluid flows in the first coil pipe 635c is smaller than the cross-sectional area of the flow passages through which process fluid flows in the first upstream pipe 635a and the first downstream pipe 635b, the process fluid may be decreased in temperature and liquefied when moving from the first upstream pipe 635a to the first coil pipe 635c due to the Joule-Thomson effect.

The fluid discharge unit 700 discharges processing fluid from the processing space of the housing 510. The fluid discharge unit 700 may include parts such as a discharge pipe 710, a pressure relief valve 731, and a pressure regulating member 733.

The discharge pipe 710 discharges processing fluid from the processing space. The discharge pipe 710 may include a second upstream pipe 710a, a second downstream pipe 710b, and an inner pipe 710c.

The second downstream pipe 710b is connected to the second body 513. The second downstream pipe 710b is connected to the center of the second body 513. The processing fluid that has completed processing is discharged from the processing space through the second upstream pipe 710a. The second upstream pipe 710a is provided with a constant cross-sectional area, through which the processing fluid flows, in its longitudinal direction.

The second downstream pipe 710b is connected to the second coil pipe 710c to be described below and discharges processing fluid that has completed processing to the outside. The second downstream pipe 710b is provided with a constant cross-sectional area, through which the processing fluid flows, in its longitudinal direction. According to an embodiment, the cross-sectional area of the second upstream pipe 710a and the cross-sectional area of the second downstream pipe 710b may be provided to be the same. A pressure relief valve 731 and a pressure regulating member 733 may be installed in the second downstream pipe 710b.

The pressure relief valve 731 allows processing fluid to be selectively discharged from the processing space. The pressure relief valve 731 can make processing fluid selectively flow through the discharge pipe 710. The pressure relief valve 731 may be an on/off valve.

The pressure regulating member 733 keeps the pressure of the processing space constant at a set pressure. For example, the pressure regulating member 733 can measure the pressure of processing fluid flowing through the discharge pipe 710. The pressure regulating member 733 can measure the pressure of the processing space on the basis of the pressure of processing fluid flowing through the discharge pipe 710, and can adjust the discharge flow rate per unit time of the processing fluid that is discharged through the discharge pipe 710 to maintain the pressure of the processing space at a set pressure. The pressure regulating member 733 may be a Back Pressure Regulator (BPR).

The inner pipe 710c is connected to the second upstream pipe 710a and the second downstream pipe 710b. The inner pipe 710c may be a coil pipe. Hereafter, for the convenience of description, the inner pipe 710c is described with the case where it is a coil pipe, and the inner pipe 710c is referred to as the second coil pipe 710c.

The second coil pipe 710c is disposed to be extendable and contractible in the vertical direction. The second coil pipe 710c can be extended in the vertical direction by movement of the second body 513 when the second body is driven in the vertical direction. The cross-sectional area of the flow passage through which processing fluid flows in the second coil pipe 710c may be smaller than the cross-sectional area of the flow passages through which processing fluid flows in the second upstream pipe 710a and the second downstream pipe 710b.

The first coil pipe 635c is provided in a structure that surrounds the second coil pipe 710c. As a result, compared to when two coil pipes 5350 and 5450 are provided independently, the total area occupied by the first coil pipe 635c and the second coil pipe 710c is reduced.

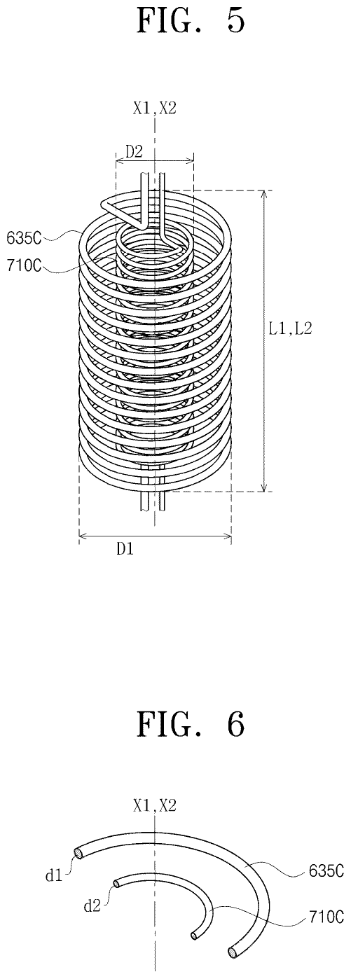

FIG. 5 is a view schematically showing the structure of a first coil pipe and a second coil pipe according to an embodiment of the present disclosure.

Referring to FIG. 5, the direction of the central axis X2 of the second coil pipe 710c is the same as the direction of the central axis X1 of the first coil pipe 635c. For example, the central axis X2 of the second coil pipe 710c may be the same as the central axis X1 of the first coil pipe 635c. The axial length L1 of the first coil pipe 635c and the axial length L2 of the second coil pipe 710c may be the same.

Meanwhile, a connection port to which the first coil pipe 635c, the first upstream pipe 635a, and the first downstream pipe 635b are connected may be provided to be spaced apart from the center axis X1 of the first coil pipe 635c. Similarly, a connection port to which the second coil pipe 710c, the second upstream pipe 710a, and the second downstream pipe 710b are connected may be provided to be spaced apart from the center axis X2 of the second coil pipe 710c.

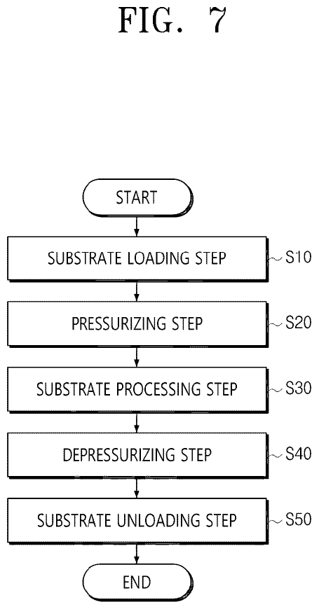

FIG. 6 is a view schematically showing a part of the appearance when the first coil pipe and the second coil pipe according to an embodiment of the present disclosure are cut along a plane including the central axis.

Referring to FIG. 5 and FIG. 6, when viewed from above, the diameter (hereinafter referred to as a first diameter D1) of the occupied area of the first coil pipe 635c is provided to be larger than the diameter (hereinafter referred to as a second diameter D2) of the occupied area of the second coil pipe 710c. The smaller the diameter of the occupied area or the larger the cross-sectional area of the flow passage through which processing fluid flows in a coil pipe when viewed from above, the larger the required compressive force and/or tensile force for extension/contraction.

In an embodiment of the present disclosure, since the first diameter D1 is provided to be larger than the second diameter D2, the cross-sectional area d1 of the flow passage through which processing fluid flows in the first coil pipe 635c is provided to be larger than the cross-sectional area d2 of the flow passage through which processing fluid flows in the second coil pipe 710c. Accordingly, the deviation between the compressive force and/or tensile force required for the extension/contraction of the first coil pipe 635c and the compressive force and/or tensile force required for the extension/contraction of the second coil pipe 710c can be reduced.

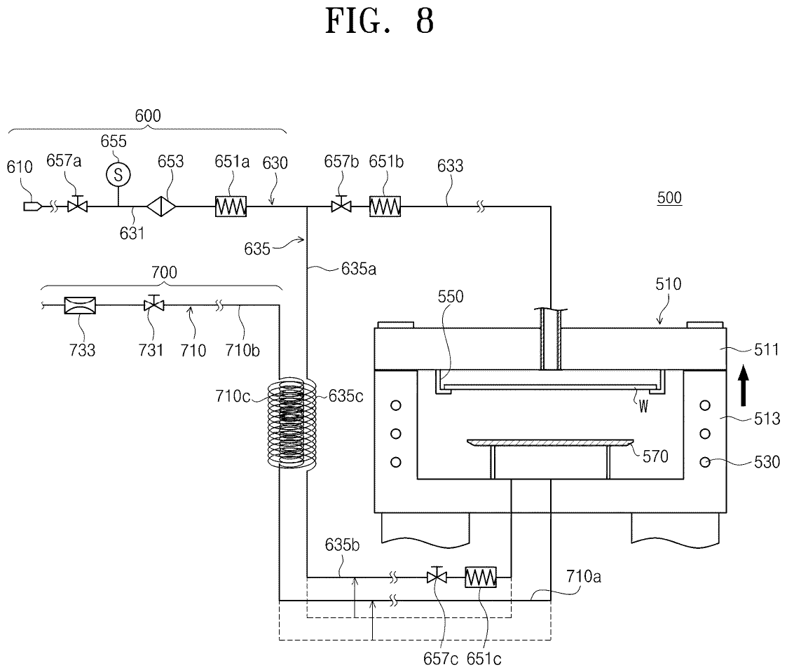

FIG. 7 is a flowchart illustrating a method of performing a supercritical drying process. A supercritical drying process includes a substrate loading step of loading a substrate W into the processing space (S10), a pressurizing step of pressurizing the atmosphere in the processing space to a pressure above a critical pressure (S20), a substrate processing step of processing the substrate at a set pressure (S30), a depressurizing step of depressurizing the atmosphere in the processing space to the atmospheric pressure (S40), and a substrate unloading step of discharging the substrate W from the processing space (S50).

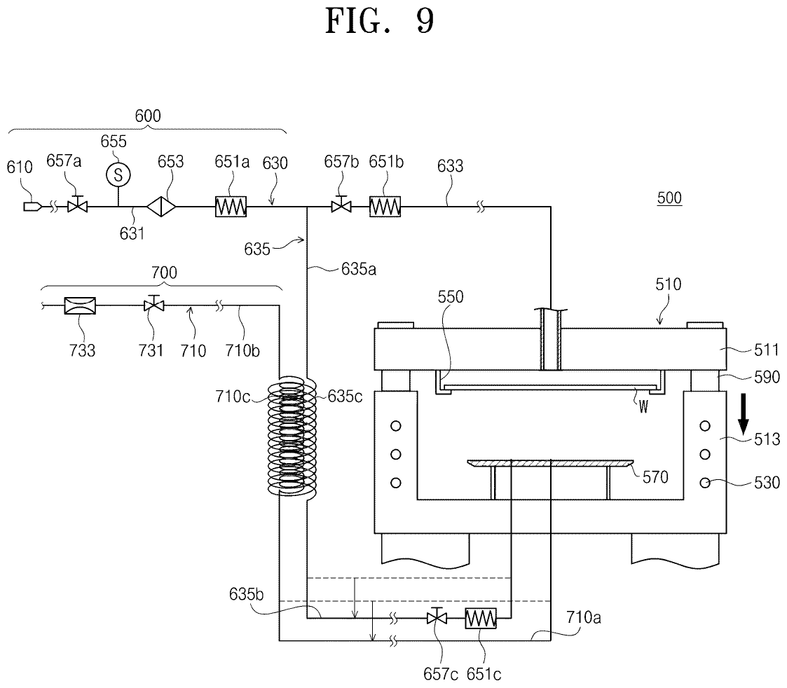

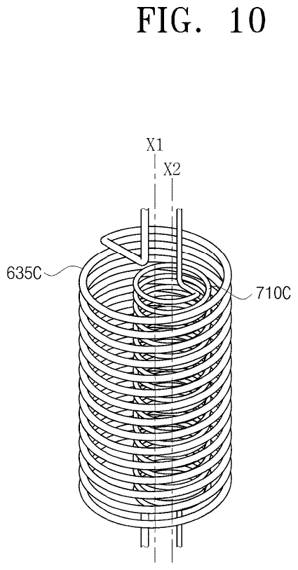

FIG. 8 is a view schematically showing the drying chamber when a second body of a housing is raised with respect to a first body in a substrate loading step and FIG. 9 is a view schematically showing the drying chamber when a second body of a housing is lowered with respect to a first body in a substrate loading step.

Referring to FIG. 8 and FIG. 9, when the second body 513 is raised or lowered, the heights of the main supply pipe 631, the upper supply pipe 633, the first upstream pipe 635a, and the second downstream pipe 710b are fixed.

As shown in FIG. 8, when the second body 513 is raised such that the processing space is closed, the first downstream pipe 635b and the second upstream pipe 710a are raised with the second body, and the first coil pipe 635c and the second coil pipe 710c are compressed.

Further, as shown in FIG. 9, when the second body 513 is lowered such that the processing space is opened, the first downstream pipe 635b and the second upstream pipe 710a are lowered with the second body, and the first coil pipe 635c and the second coil pipe 710c are tensioned.

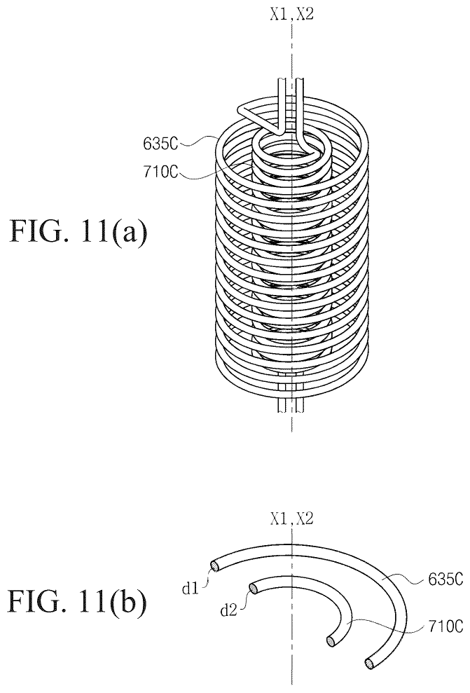

In the example described above, it was described that the central axis X1 of the first coil pipe 635c and the central axis X2 of the second coil pipe 710c are the same. However, as shown in FIG. 10, the directions of the center axes X1 of the first coil pipe 635c and the direction of the center axis of the second coil pipe 710c are the same, but the center axis X1 of the first coil pipe 635c and the center axis X2 of the second coil pipe 710c may be spaced apart.

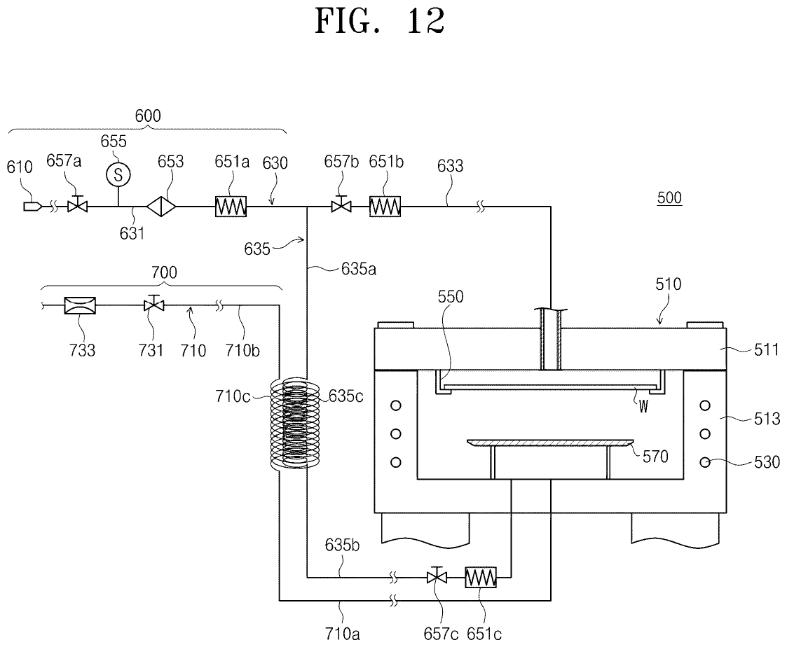

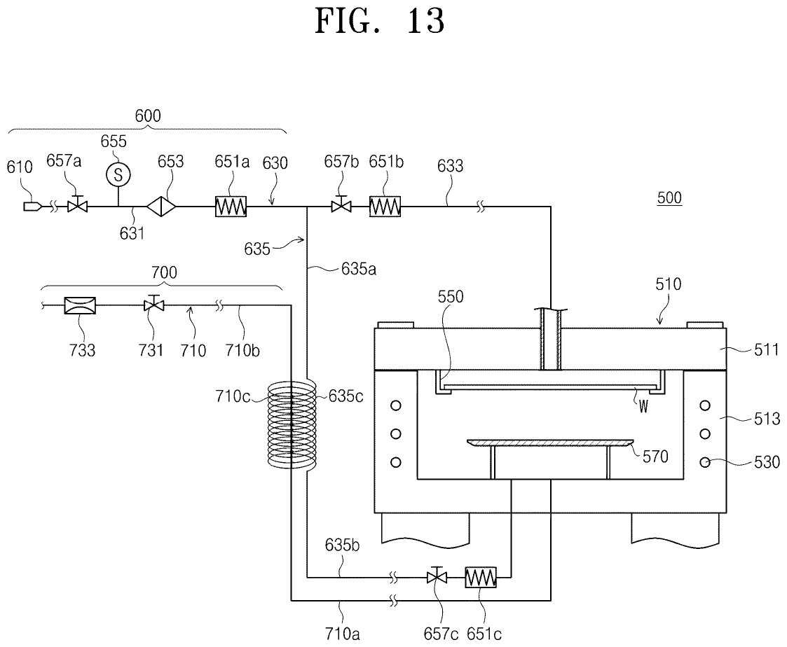

In the embodiment of FIG. 6 described above, it was described that the cross-sectional area d1 of the flow passage through which processing fluid flows in the first coil pipe 635c is provided to be larger than the cross-sectional area d2 of the flow passage through which processing fluid flows in the second coil pipe 710c. However, as shown in FIG. 11 (a) and FIG. 11 (b), the cross-sectional area d1 of the flow passage through which processing fluid flows in the first coil pipe 635c is provided to be the same as the cross-sectional area d2 of the flow passage through which processing fluid flows in the second coil pipe 710c.

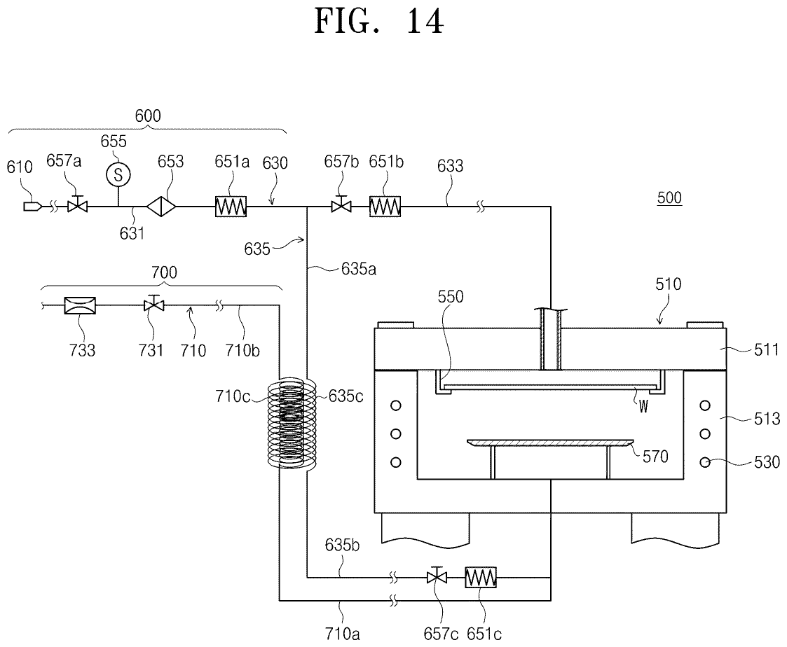

In the examples described above, a structure in which the first coil pipe 635c of the supply pipe 630 surrounds the second coil pipe 710c of the discharge pipe 710 when viewed from above was described. However, as shown in FIG. 12, the second coil pipe 710c of the discharge pipe 710 may be provided in a structure that surrounds the first coil pipe 635c of the supply pipe 630.

In the examples described above, the inner pipe 710c of the discharge pipe 710 is the second coil pipe 710c. However, as shown in FIG. 13, the inner pipe 710c may be a straight pipe, or it may be provided as a flexible pipe (not shown) that is extendable and contractible in the vertical direction.

In the examples described above, the first downstream pipe 635b of the supply pipe 630 and the second upstream pipe 710a of the discharge pipe 710 are each directly connected to the second body 513. However, as shown in FIG. 14, the first downstream pipe 635b and the second upstream pipe 710a may share a port that is directly connected to the second body 513, and through that port, processing fluid can be supplied or discharged.

In the embodiment described above, a liquid such as a cleaning liquid is supplied to substrates W to perform liquid processing on the substrates W, and supercritical fluid is supplied to dry the substrates W. However, the technical concept of the present disclosure can be applied to apparatuses where various processes, such as etching processes and developing processes, are performed using a processing fluid to process substrates W, in addition to the apparatus for performing the supercritical drying process.

In the examples described above, it was described that the second body 513 is raised and lowered relative to the first body 511 to open and close the processing space. However, unlike this, the second body 513 may be provided to be moved in the left and right directions with respect to the first body 511.

In the examples described above, it was described that the second body 513 is raised and lowered relative to the first body 511 to open and close the processing space. However, unlike this, in the substrate loading step S10 or the substrate unloading step S50, the first body 511 may be raised and lowered with respect to the second body 513.

In the examples described above, it was described that the heaters 651b and 651c and the filters 657b and 657c are installed in the upper supply pipe 633 and the first downstream pipe 635b of the lower supply pipe 635, respectively. However, unlike this, a heater, filter, sensor, or valve may be optionally installed in the first downstream pipe 635b of the upper supply pipe 633 and the lower supply pipe 635, or no additional parts may be installed.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate processing apparatus, comprising:
a housing having a first body and a second body providing a processing space therein for processing substrates by being combined with each other;
an actuator sealing or opening the processing space by moving up and down the second body with respect to the first body;
a supply pipe supplying fluid to the processing space; and
a discharge pipe discharging fluid from the processing space,
wherein the supply pipe includes:
a first upstream pipe connected to a fluid supply source;
a first downstream pipe connected to the second body; and
a first coil pipe connected to the first upstream pipe and the first downstream pipe and having a coil shape extendable and contractible in a vertical direction, and
wherein the discharge pipe includes:
a second upstream pipe connected to the second body;
a second downstream pipe disposed downstream of the second upstream pipe; and
a second coil pipe connected to the second upstream pipe and the second downstream pipe and having a coil shape extendable and contractible in a vertical direction, and
any one coil pipe of the first coil pipe and the second coil pipe is disposed to surround the other coil pipe when viewed from above.

2. The substrate processing apparatus of claim 1, wherein the first coil pipe is disposed to surround the second coil pipe when viewed from above.

3. The substrate processing apparatus of claim 2, wherein a cross-sectional area of the second coil pipe is provided to be smaller than a cross-sectional area of the first coil pipe.

4. The substrate processing apparatus of claim 3, wherein the cross-sectional area of the first coil pipe is provided to be the same as a cross-sectional area of the first upstream pipe and a cross-sectional area of the first downstream pipe.

5. The substrate processing apparatus of claim 4, wherein the cross-sectional area of the second coil pipe is provided to be smaller than a cross-sectional area of the second upstream pipe and a cross-sectional area of the second downstream pipe.

6. The substrate processing apparatus of claim 1, wherein a cross-sectional area of the first coil pipe is provided to be the same as a cross-sectional area of the second coil pipe.

7. The substrate processing apparatus of claim 1, wherein a central axis of the first coil pipe is disposed to be spaced apart from a central axis of the second coil pipe when viewed from above.

8. The substrate processing apparatus of claim 1, wherein a central axis of the first coil pipe and a central axis of the second coil pipe are provided to coincide with each other when viewed from above.

9. The substrate processing apparatus of claim 1, further comprising an upper supply pipe coupled to the first body and supplying fluid to the processing space,
wherein one of the supply pipe and the discharge pipe is directly connected to a center of the second body, and
the other one of the supply pipe and the discharge pipe is directly connected to a point offset from the center of the second body.

10. The substrate processing apparatus of claim 1, wherein an axial length of the first coil pipe and an axial length of the second coil pipe are provided to be the same.

11. A substrate processing apparatus, comprising:
a housing having a first body and a second body providing a processing space therein for processing substrates by being combined with each other;
an actuator sealing or opening the processing space by moving the second body with respect to the first body;
a supply pipe supplying fluid to the processing space; and
a discharge pipe discharging fluid from the processing space,
wherein any one pipe of the supply pipe and the discharge pipe has a first coil pipe having a coil shape extendable and contractible along a relative movement direction, and the other one pipe of the supply pipe and the discharge pipe has an inner pipe that passes through a region surrounded by the first coil pipe.

12. The substrate processing apparatus of claim 11, wherein the inner pipe is a second coil pipe having a coil shape extendable and contractible along the relative movement direction.

13. The substrate processing apparatus of claim 11, wherein a longitudinal direction of the inner pipe is provided to be the same as an axial direction of the first coil pipe.

14. The substrate processing apparatus of claim 11, wherein the supply pipe includes:
a first upstream pipe connected to a fluid supply source;
a first downstream pipe connected to the second body; and
the first coil pipe connected to the first upstream pipe and the first downstream pipe, and
the discharge pipe includes:
a second upstream pipe connected to the second body;
a second downstream pipe disposed downstream of the second upstream pipe; and
the inner pipe connected to the second upstream pipe and the second downstream pipe.

15. The substrate processing apparatus of claim 11, wherein the relative movement direction is a vertical direction.

16. The substrate processing apparatus of claim 12, wherein a cross-sectional area of the second coil pipe is provided to be smaller than a cross-sectional area of the first coil pipe.

17. The substrate processing apparatus of claim 14, wherein a cross-sectional area of the first coil pipe is provided to be the same as a cross-sectional area of the first upstream pipe and a cross-sectional area of the first downstream pipe.

18. A substrate processing apparatus, comprising:
a housing having a first body and a second body providing a processing space therein for processing substrates by being combined with each other;
a supporting unit coupled to the first body and supporting a substrate in the processing space;
an actuator sealing or opening the processing space by moving up and down the second body with respect to the first body;
a supply pipe supplying fluid to the processing space; and
a discharge pipe discharging fluid from the processing space,
the supply pipe includes:
a first upstream pipe connected to a fluid supply source;
a first downstream pipe connected to the second body; and
the first coil pipe connected to the first upstream pipe and the first downstream pipe, and having a coil shape,
the discharge pipe includes:
a second upstream pipe connected to the second body;
a second downstream pipe disposed downstream of the second upstream pipe; and
the second coil pipe connected to the second upstream pipe and the second downstream pipe, and having a coil shape,
the first coil pipe is disposed to surround the second coil pipe when viewed from above, and
a cross-sectional area of the second coil pipe is provided to be smaller than a cross-sectional area of the first coil pipe.

19. The substrate processing apparatus of claim 18, wherein the cross-sectional area of the first coil pipe is provided to be the same as the cross-sectional area of the first upstream pipe and a cross-sectional area of the first downstream pipe; and
the cross-sectional area of the second coil pipe is provided to be smaller than a cross-sectional area of the second upstream pipe and a cross-sectional area of the second downstream pipe.

20. The substrate processing apparatus of claim 18, further comprising an upper supply pipe coupled to the first body and supplying fluid to the processing space,
wherein one of the supply pipe and the discharge pipe is directly connected to a center of the second body, and
the other one of the supply pipe and the discharge pipe is directly connected to a point offset from the center of the second body.
